(19) United States
(12) Patent Application Publication
(10) Pub. No.: US 2006/0206773 A1
(43) Pub. Date: Sep. 14, 2006

(54) Tester simulation system and tester simulation method using same

(75) Inventor: Sadaki Anzai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: YOKOGAWA ELECTRIC CORPORATION

(21) Appl. No.: 11/366,421

(22) Filed: Mar. 3, 2006

(30) Foreign Application Priority Data
Mar. 4, 2005 (JP) 2005-061224

(51) Int. Cl. G01R 31/28; G06F 11/00

(52) U.S. Cl. 714/742

(57) ABSTRACT

It is an object of the invention to implement a tester simulation system capable of checking timing margins of an input pattern in a short time, and a tester simulation method using the same. The invention is an improvement of a tester simulation system for simulating a test by a tester as a device under test based on a test pattern. The tester simulation system comprises a DUT model, and a tester model for adding an unknown value for a desired period to edges of an input pattern of the test pattern before outputting to the DUT model while comparing outputs of the DUT model with an expected value pattern of the test pattern, respectively, to thereby determine that the case where the outputs of the DUT model are at levels differing from those for expected values or at the unknown value signifies a fail.

### FIELD OF THE INVENTION

The invention relates to a tester simulation system for simulating a test by use of a tester as a device under test, for example, ICs, LSIs, and so forth, based on a test pattern, and a tester simulation method using the same, and more particularly, to a tester simulation system capable of checking timing margins of an input pattern in a short time, and a tester simulation method using the same.

### BACKGROUND OF THE INVENTION

A tester (an IC tester) is to provide a device under test (hereinafter referred to as a DUT) with an input pattern on the basis of a test program, and to compare an output from the DUT with an expected value pattern, thereby determining whether or not the DUT is acceptable. A simulation has lately been carried out using a DUT model and a tester model, before actually testing the DUT by use of a tester, thereby checking an operation of the test program. Such a system has since been disclosed in, for example, the following Patent Document 1, and so forth.

[Patent Document 1] JP 2003-256493 A

As shown in FIG. 6, a memory 1 stores a test program including test patterns comprising an input pattern, an expected value pattern, and so forth. A simulation means 2 simulates a circuit operation of a tester on the basis of the test program of the memory 1. The simulation means 2 has a tester model 21, and a DUT model 22. The tester model 21 simulates the circuit operation of the tester on the basis of the test program of the memory 1. The DUT model 22 exchanges signals with the tester model 21 to thereby simulate a circuit operation of the DUT such as, for example, an IC, an LSI, and so forth.

An operation of the system is described hereinafter. The simulation means 2 reads the test program of the memory 1 to thereby operate the tester model 21 according to the test program. The tester model 21 outputs the input pattern to the DUT model 22 on the basis of the test program. The DUT model 22 outputs to the tester model 21 according to the input pattern. The tester model 21 compares an output of the DUT model 22 with the expected value pattern of the test program. Thus, an operation of the test program is checked by the tester model 21 and the DUT model 22.

There is described hereinafter a test simulation in the case where the DUT model 22 comprises, for example, an OR (logical sum) circuit, EOR (exclusive logical sum) circuit, AND (logical product) circuit, and a flip-flop model that latches those circuits, respectively, and respective outputs of those circuits are delivered.

FIG. 7 is a view showing a timing chart of a simulation of the DUT model 22 described. In the figure, FIG. 7(A) and FIG. 7(B) denote input signals A, B, respectively, FIG. 7(C) to FIG. 7(E) output signals a to c of an OR circuit, an EOR circuit, and an AND circuit, respectively, FIG. 7(F) a clock clk outputted by the tester model 21, and FIG. 7(G) to FIG. 7(I) output signals d to f of a flip-flop of the DUT model 22. Herein, the upward dotted-line arrow denotes strobe timing indicating an expected value “H”, and the downward dotted-line arrow denotes strobe timing indicating an expected value “L”. Further, the upward arrow of the clock clk shows that the flip-flop latches a signal on the rising edge thereof. And a long dashed double-dotted line indicates a test rate of the tester.

The tester model 21 outputs the input pattern including the-input signals A, B and the clock clk to the DUT model 22. Then, the DUT model 22 outputs the output signals a to f to the tester model 21. The tester model 21 compares expected values with the output signals a to f at the strobe timings.

In a real tester, digital signals generated by a signal generator on the basis of the test pattern are applied to input pins of the DUT via a driver and the output signals from output pins of the DUT are checked against the expected values based on the test pattern. However, in the case of testing with the real tester, there exist electrical problems of a tester, such as an absolute error, a deviation of an actual edge timing from a specified set value, and so forth, so that a timing chart will not be like the timing chart at ideal timings, as shown in FIG. 7. It happens that the input signal A is given rather later, or the input signal B is given rather earlier.

Combination of such timing errors varies depending on a tester type, individual differences among the same type testers, difference between pins of the same tester, and so forth, so that deviation amounts can differ from each other to thereby cause various combination of errors in the direction of either plus or minus to occur.

For example, in the case of an error causing an edge timing of the input signal A to be delayed, a timing chart will be one as shown in FIG. 8. That is, a fail-occurring spot occurs at four locations. Herein, the spot of a dotted-line arrow marked with “F” under the arrow indicates the fail-occurring spot. Further, one dotted chain line indicates a waveform at ideal timings.

Next, in the case of an error causing the edge timing of the input signal A to be earlier, and an edge timing of the input signal B to be delayed, a timing chart will be one as shown in FIG. 9. That is, a fail-occurring spot occurs at seven locations.

Then, in the case of combination of all errors causing the respective edge timings of the input signals A, B to be earlier, same, and delayed respectively, fail-occurring spots at eleven locations are shown in FIG. 10. Waveforms in FIG. 10 show ideal waveforms.

There has thus far been no effect of the fails on latching at the clock clk, however, in the case where the edge timing of the input signal A is delayed, and timing of the clock clk becomes earlier, a fail occurs to outputs of the flip-flop, as shown in FIG. 11.

Thus, checking of timing margins of the real tester used to be executed by deviating timings of the input pattern with the use of the simulation means 2.

### SUMMARY OF THE INVENTION

With the latest LSIs, a circuit scale has since become huge, and time required for simulation of a test pattern once has come to take many hours. Further, because the number of pins has since increased to, for example, 100 or more, the number of combinations of timing errors becomes considerable. Also, even if some of combinations of cases of edge timings being too early, ±0, and too late, respectively, are selected to thereby repeat a simulation taking many hours, it sometimes happens that there remains a possibility of overlooking fail points occurring in a manner like a pulse narrow in width. In order to eliminate such a possibility, there results an increase in check point, that is, an increase in the number of simulations.

Under such circumstances, it has become impractical to execute simulations to check whether or not there exist margins for the edge timing errors against the input signals.

However, many of the latest LSIs are operated at a high speed, and adverse effects of the timing errors of the tester have become relatively greater, so that the number of the cases where correct checking of the expected values cannot be implemented has conspicuously increased.

It is desired to carry out verification of the tester including its timing errors by executing simulations in advance, however, since the simulations takes too much time, there has existed a problem in that the simulations cannot be undertaken.

It is therefore an object of the invention to implement a tester simulation system capable of checking timing margins of an input pattern in a short time, and a tester simulation method using the same.

To that end, the invention in its first aspect provide a tester simulation system for simulating a test by a tester as a device under test (DUT) based on a test pattern, said tester simulation system comprising a DUT model for simulating a circuit operation of the device under test, and a tester model for simulating the circuit operation of the tester and adding an unknown value for a desired period to edges of an input pattern of the test pattern before outputting to the DUT model while comparing outputs of the DUT model with an expected value pattern of the test pattern, respectively, to thereby determine that the case where the outputs of the DUT model are at levels differing from those for expected values or at the unknown value signifies a fail.

The tester simulation system with those features preferably further comprises driver models for adding the unknown value for the desired period to the edges of the input pattern before outputting, and comparator models for comparing the outputs of the DUT model with the expected value pattern at timings of strobes to thereby determine that the case where the outputs of the DUT model are at the levels differing from those for the expected values or at the unknown value signifies a fail.

The tester simulation system with those features preferably further comprises a signal generator model provided in the tester model, for outputting the input pattern to the driver models and the expected value pattern to the comparator models, according to the tester pattern, while providing the comparator models with strobes, respectively.

Further, with the tester simulation system according to the first aspect of the invention, the tester model may comprise a signal generator model for adding the unknown value for the desired period to the edges of the input pattern according to the tester pattern before outputting, and outputting the expected value pattern and strobes, and comparator models for comparing the outputs of the DUT model with the expected value pattern of the signal generator model at timings of strobes of the signal generator model, respectively, to thereby determine that the case where the outputs of the DUT model are at the levels differing from those for the expected values or at the unknown value signifies a fail.

Still further, the invention in its second aspect provide a tester simulation method for simulating a test by a tester as a device under test (DUT) based on a test pattern, said tester simulation comprising a step of adding an unknown value for a desired period to edges of an input pattern of the test pattern to a tester model for simulating a circuit operation of the tester before outputting, a step of receiving outputs of the tester model to thereby cause DUT model to simulate a circuit operation of the device under test, and a step of causing the tester model to compare outputs of the DUT model with an expected value pattern of the test pattern to thereby determine that the case where the outputs of the DUT model are at levels differing from those for expected values or at the unknown value signifies a fail.

With the present invention, the tester model adds the unknown value for the desired period to the edges of the input pattern, and compares the outputs of the DUT model with expected values, respectively, to thereby determine that the case where the outputs of the DUT model are at the levels differing from those for the expected values or at the unknown value signifies a fail, so that timing margins can be checked in a short time Furthermore, since the unknown value for the desired period is added, it is possible to check the timing margins throughout the desired period.

### BRIEF DESCRIPTION OF THE DRAWINGS

FIG. 1 is a block diagram of one embodiment of a tester simulation system according to the invention;

FIGS. 2A thru 2C are views showing respective truth tables of basic circuits of the invention;

FIGS. 3A and 3B are timing charts showing an operation of the system shown in FIG. 1;

FIGS. 4A thru 4I are timing charts showing another operation of the system shown in FIG. 1;

FIGS. 5A thru 5I are timing charts showing still another operation of the system shown in FIG. 1;

FIG. 6 is a block diagram of a conventional tester simulation system;

FIGS. 7A thru 7I are charts showing an operation of the system shown in FIG. 6;

FIGS. 8A thru 8I are timing charts showing another operation of the system shown in FIG. 6;

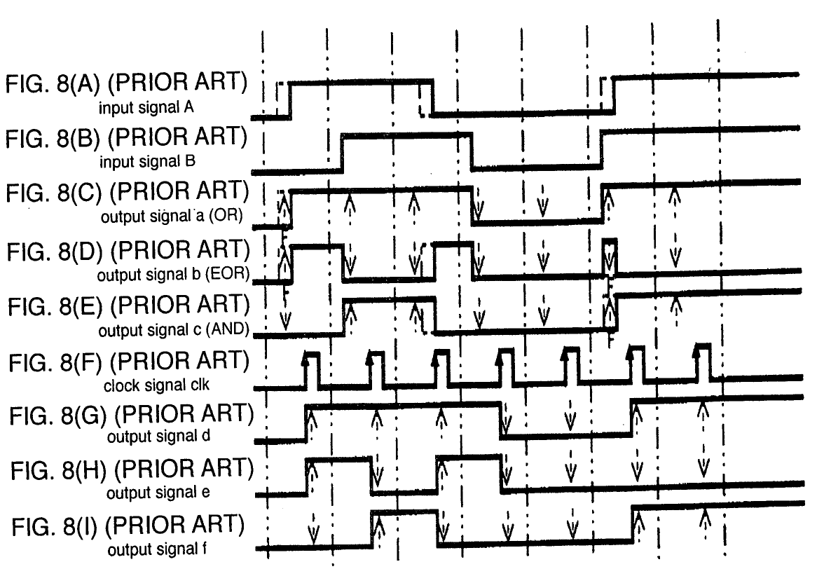

FIGS. 9A thru 9I are timing charts showing still another operation of the system shown in FIG. 6;

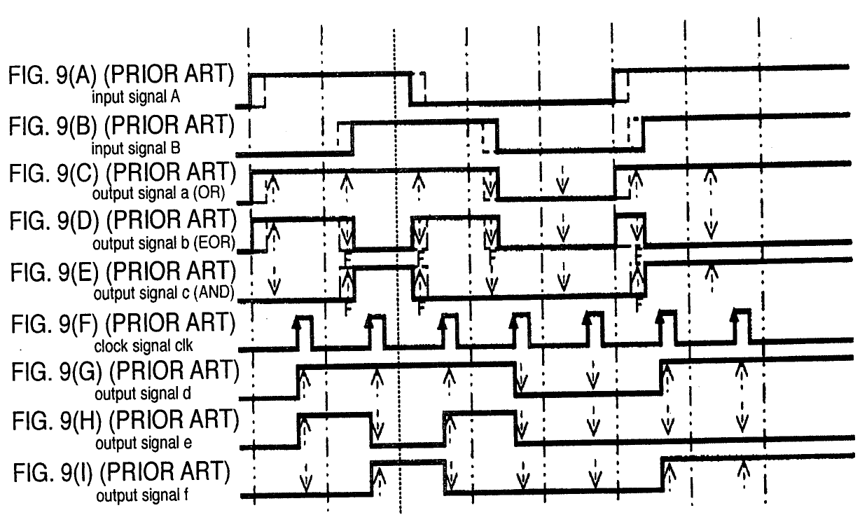

FIGS. 10A thru 10I are timing charts showing a further operation of the system shown in FIG. 6; and

FIGS. 11A thru 11I are timing charts showing a still further operation of the system shown in FIG. 6.

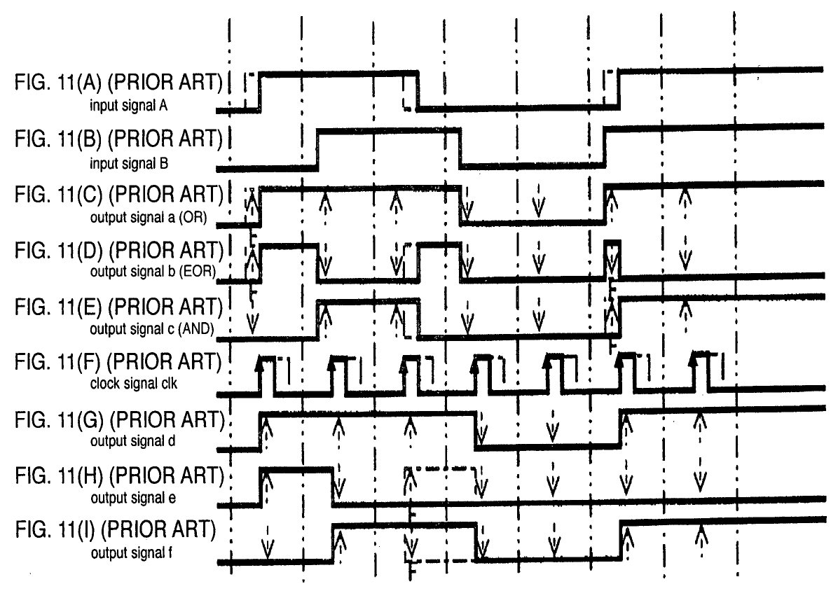

### PREFERRED EMBODIMENTS OF THE INVENTION

An embodiment of the invention is described hereinafter with reference to the accompanying drawings.

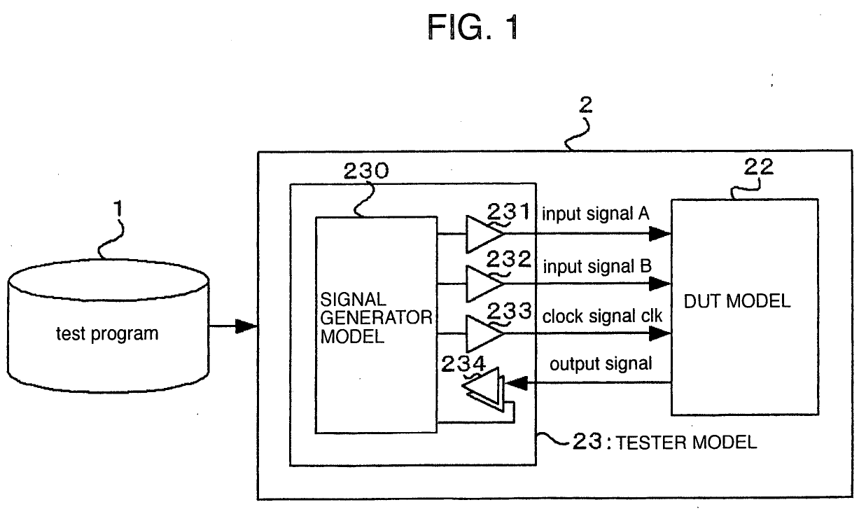

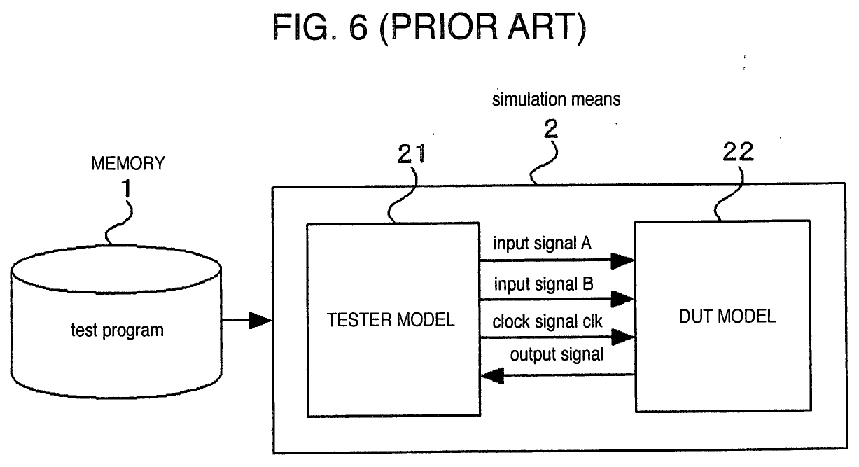

FIG. 1 is a block diagram of one embodiment of a tester simulation system according to the invention. In the figure, parts identical to those in FIG. 6 are denoted by like reference numerals, and description thereof is omitted.

As shown in FIG. 1, a tester model 23 is provided in place of the tester model 21, and simulates a circuit operation of a tester, based on a test program of a memory 1, to thereby add an unknown value for a desired period to edges of an input pattern of a test pattern before outputting to a DUT model 22 while comparing outputs of the DUT model 22 with an expected value pattern of the test pattern to thereby determine that the case where the outputs of the DUT model 22 are at levels differing from expected values or at the unknown value signifies a fail. The tester model 23 comprises a signal generator model 230, driver models 231 to 233, and a plurality of comparator models 234. The signal generator model 230 outputs signals after timing generation and waveform shaping according to test pattern data, that is, the input pattern, an expected value pattern, and strobes. The driver models 231, 232 add the unknown value for the desired period to the edges of the input pattern from the signal generator model 230 before outputting to the DUT model 22. The driver model 233 shifts timings of the input pattern from the signal generator model 230 to be thereby outputted to the DUT model 22. The comparator models 234 each compare the outputs of the DUT model 22 with the expected value pattern at timings of the strobes of the signal generator model 230 to thereby determine that the case where the outputs of the DUT model 22 are at the levels differing from those for the expected values or at the unknown value signifies a fail.

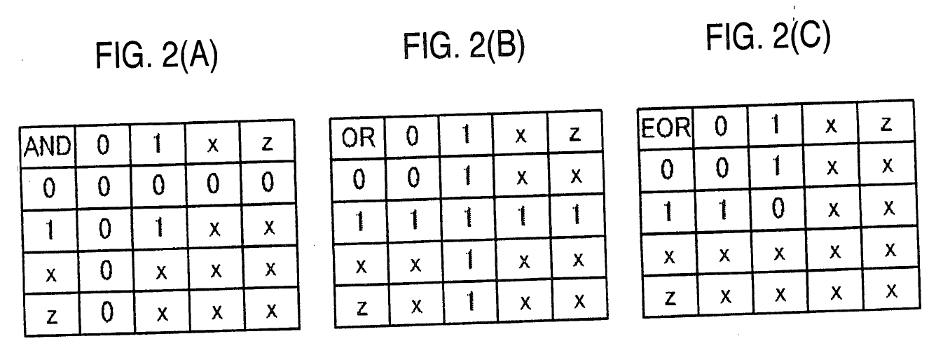

In this connection, the unknown value is a particular level referred to as an x (unknown) level existing in a simulator, besides levels such as H (high) level, L (low) level, and Z (high-z) level. An x signal is basically ignored in the case where its level is specified by other signals, and when computed by both the signals, it acts such that if one of the signals is “x”, a result is “x”. Relationship of those signals is, for example, as shown in FIG. 2. In the figure, FIG. 2(A) indicates a truth table of an AND circuit, FIG. 2(B) a truth table of an OR circuit, and FIG. 2(C) a truth table of an EOR circuit, respectively. Further, with many LSIs, some synchronous design is applied thereto, and clocks serving as a reference signal relative to the respective input signals exist, so that input levels or internal signal levels are latched at edges of the respective clocks to be transmitted to a succeeding stage. Similarly to ordinary levels, if a clock occurs in a condition where x is given, the x level is latched to be then transmitted to a succeeding stage as the x level.

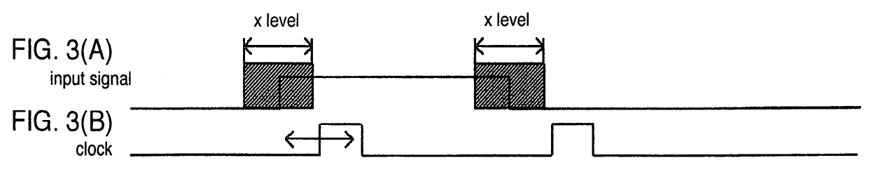

An operation of such a system described as above is described hereinafter with reference to FIG. 3. A simulation means 2 reads the test program of the memory 1, and operates the tester model 23 according to the test program. The signal generator model 230 of the tester model 23 outputs the input pattern to the driver models 231 to 233, respectively, on the basis of the test program. The driver models 231, 232 add the x level for the desired period to the edges of the input pattern, as shown in FIG. 3(A), before outputting to the DUT model 22. The driver model 233 receives the input pattern serving as the clocks, and shifts the timings of the input pattern, as shown in FIG. 3(B), to be then outputted to the DUT model 22. The DUT model 22 executes a simulation according to those input signals and clocks on the basis of the relationship shown in FIG. 2 before outputting to the tester model 23. And the comparator models 234 of the tester model 23 compare the outputs of the DUT model 22 with the expected value pattern of the test program to thereby determine that the case where the outputs of the DUT model 22 are at the same levels as those for the expected values, respectively, is a pass while the case where the outputs of the DUT model 22 are at the levels differing from those for the expected values, respectively, or at the x level, is a fail. It is evident that a margin corresponding to the desired period of the x level does not exist when a fail occurs.

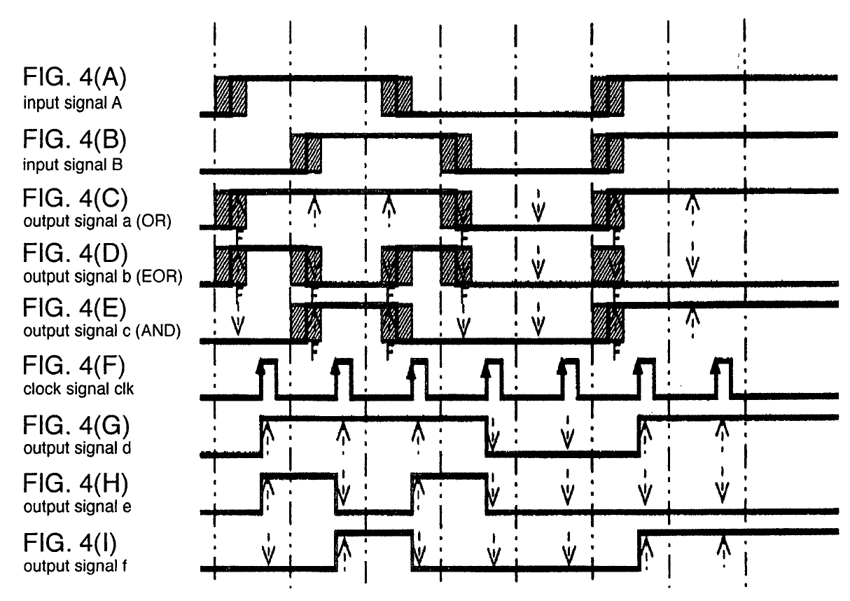

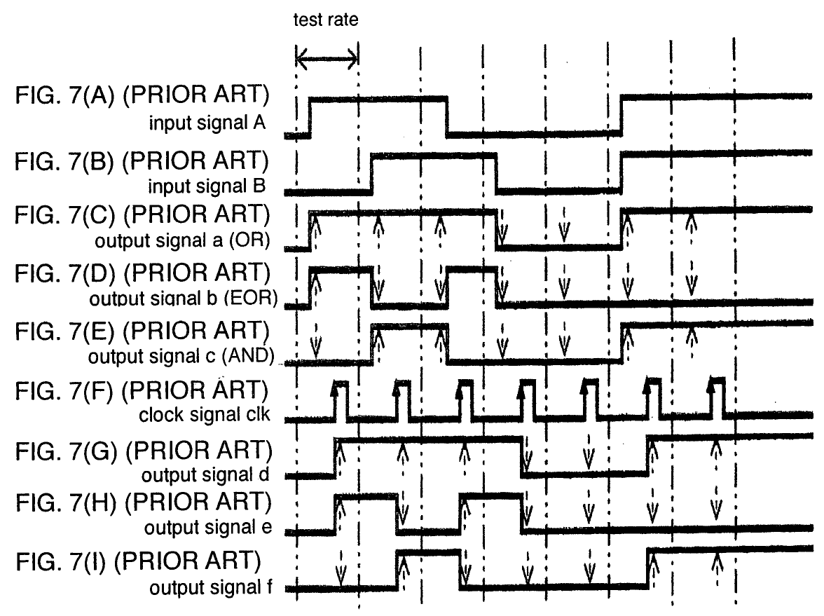

As with the case of a conventional example, there is described hereinafter a test simulation in the case where the DUT model 22 comprises, for example, the OR circuit, EOR circuit, AND circuit, and the flip-flop model that latches those circuits, respectively, and respective outputs of those circuits are delivered. FIG. 4 is a view showing a timing chart of such a simulation as described of the DUT model 22. In the figure, FIG. 4(A) to FIG. 4(I) are similar to those in FIG. 7. Herein, diagonally shaded parts in the vicinity of respective edges of the signals indicate the x level, respectively, and others signify the same as those in FIG. 7.

The signal generator model 230 of the tester model 23 outputs input signals A, B, and a clock clk. Then, the driver models 231, 232 add the x level to the desired periods of the edges of the input signals A, B of the signal generator model 230, respectively, as shown in FIG. 4(A) and FIG. 4(B), before outputting. Further, the driver model 233 outputs a clock clk without shifting timing thereof, as shown in FIG. 4(F), before outputting. According to respective outputs of those driver models 231 to 233, the DUT model 22 outputs output signals a to c, each containing the x level, as shown in FIG. 4(C) to FIG. 4(E), respectively, and outputs output signals d to f, each not containing the x level, as shown in FIG. 4(G) to FIG. 4 (I), respectively, due to the relationship shown in FIG. 2.

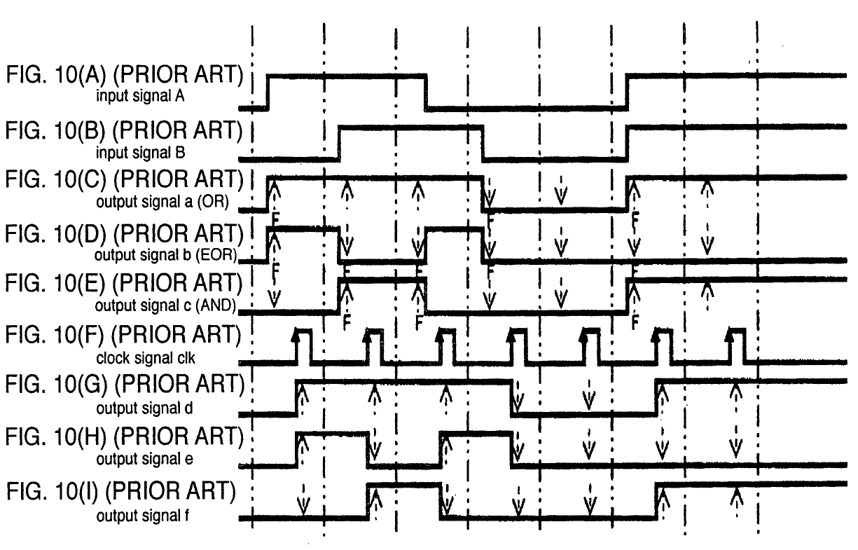

The plurality of the comparator models 234 of the tester model 23 receive the output signals a to f of the DUT model 22, respectively, and compare the output signals a to f with the expected value pattern outputted by the signal generator model 230 at the timings of the strobes. And the comparator models 234 each determine that the case where the output signals coincide with the expected value pattern, respectively, is a pass, and the case where the output signals do not coincide with the expected value pattern, or at the x level, respectively, is a fail. As a result, fail points shown in FIG. 4 coincide with fail points in FIG. 10. It follows that whether or not a timing margin exist can be found by one simulation if the x level is used.

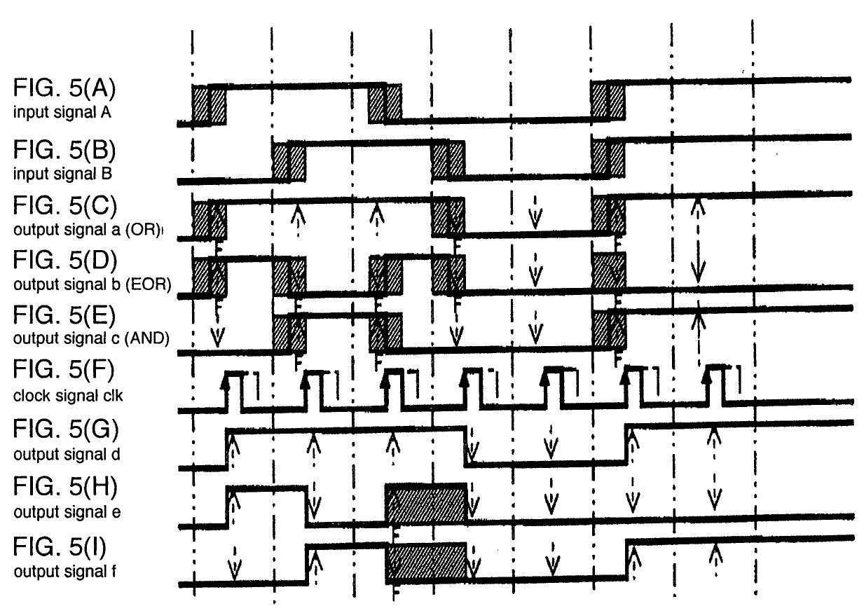

Next, there is described hereinafter the case of shifting timings of the clock clk with reference to FIG. 5. In this case, the driver model 233 shifts the timings of the clock clk outputted by the signal generator model 230 somewhat earlier to thereby output to the DUT model 22. As a result, the DUT model 22 outputs the output signals each containing the x level, other than the output signal d, as shown in FIG. 5(G) to FIG. 5(I). Other operations are the same as described in the foregoing, omitting therefore description thereof. The clock clk is a reference signal, and is therefore unable to set the x level, but can execute checking by bringing forward or delaying its timing.

Thus, the tester model 23 adds the x level to the edges of the input pattern, and compares the outputs of the DUT model 22 with the expected values, respectively, determining that the case where the outputs of the DUT model 22 are at the levels differing from those for the expected values or at the x level is a fail, so that timing margins can be checked in a short time.

Since the x level for the desired period is added, it is possible to check the timing margins throughout the desired period. That is, it is possible to eliminate a possibility of overlooking fail points occurring in a manner like a pulse narrow in width between steps of shifting the timing at the time of checking the timings.

Further, the invention is not limited to a configuration described as above, and because a timing error of the input signal associated with the clock is regarded as a relative time difference of the edge of the clock, the clock itself taken as the reference signal is regarded as constant and ideal timing, so that there may be adopted a configuration wherein a simulation is executed by adding timing errors of the clock to the timing errors of the input signals, respectively, although there has thus far been shown a configuration wherein the checking is executed by shifting the timings of the clock clk.

Further with the present embodiment, a case of the system having one clock is shown, however, a plurality of clocks may be provided. In such a case, there are repeated simulations corresponding to the number of combinations that the timings of the plurality of the clocks are shifted. Furthermore, the simulations are executed by adding timing errors of the plurality of the clocks to the timing errors of the input signals, respectively. As the clocks are far less in number than the input signals, even if there are carried out the simulations corresponding to the number of combinations that the timings of the plurality of the clocks are shifted, it is possible to implement simulations for combinations far less in number than all the combinations.

Further, there has been shown a configuration wherein the driver models 231, 232 each insert the x level, and the driver model 233 shifts the timings, however, there may be adopted instead a configuration wherein the signal generator model 230 inserts the x level against the input pattern and shifts the timings. In such a case, the tester model 23 can dispense with the driver models 231 to 233.

Still further, the desired periods of the x level for the input signals may vary by the pin of the DUT model 22, or may remain unchanged. Further, setting of the desired periods may be designated by a pin group of the tester model or on a pin-by-pin basis.

Yet further, there has been shown a configuration wherein the driver models 231 to 233, and the comparator models 234 are provided against input, output, and clock pins of the DUT model 22, respectively, however, as with the real tester, there may be adopted instead a configuration wherein the driver models, and the comparator models are provided for every pin of the tester model. Further, the driver models may have both a function of inserting the x level, and a function of shifting the timings.

Further, in place of a configuration wherein the desired periods for adding the x level are to be preset, a configuration may be adopted such that the desired periods for adding the x level are set in the driver models 231, 232 of the simulation means 2 by input means such as a keyboard, mouse, and so forth, or various desired period setting as stored in the memory are read by the simulation means 2 to be then set in the driver models 231, 232.

What is claimed is:

1. A tester simulation system for simulating a test by a tester as a device under test (DUT) based on a test pattern, said tester simulation system comprising:
a DUT model for simulating a circuit operation of the device under test; and
a tester model for simulating the circuit operation of the tester and adding an unknown value for a desired period to edges of an input pattern of the test pattern before outputting to the DUT model while comparing outputs of the DUT model with an expected value pattern of the test pattern, respectively, to thereby determine that the case where the outputs of the DUT model are at levels differing from those for expected values or at the unknown value signifies a fail.

2. A tester simulation system according to claim 1, further comprising:
driver models for adding the unknown value for the desired period to the edges of the input pattern before outputting; and
comparator models for comparing the outputs of the DUT model with the expected value pattern at timings of strobes to thereby determine that the case where the outputs of the DUT model are at the levels differing from those for the expected values or at the unknown value signifies a fail.

3. A tester simulation system according to claim 2, further comprising a signal generator model provided in the tester model, for outputting the input pattern to the driver models and the expected value pattern to the comparator models, according to the tester pattern, while providing the comparator models with strobes, respectively.

4. A tester simulation system according to claim 1, wherein the tester model comprises:
a signal generator model for adding the unknown value for the desired period to the edges of the input pattern according to the tester pattern before outputting, and outputting the expected value pattern and strobes; and
comparator models for comparing the outputs of the DUT model with the expected value pattern of the signal generator model at timings of strobes of the signal generator model, respectively, to thereby determine that the case where the outputs of the DUT model are at the levels differing from those for the expected values or at the unknown value signifies a fail.

5. A tester simulation method for simulating a test by a tester as a device under test (DUT) based on a test pattern, said tester simulation method comprising:
a step of adding an unknown value for a desired period to edges of an input pattern of the test pattern to a tester model for simulating a circuit operation of the tester before outputting;
a step of receiving outputs of the tester model to thereby cause DUT model to simulate a circuit operation of the device under test; and
a step of causing the tester model to compare outputs of the DUT model with an expected value pattern of the test pattern to thereby determine that the case where the outputs of the DUT model are at levels differing from those for expected values or at the unknown value signifies a fail.
